(19) United States
(12) Patent Application Publication
(10) Pub. No.: US 2024/0239327 A1
(43) Pub. Date: Jul. 18, 2024

(54) VEHICLE SYSTEMS AND METHODS FOR PROLONGING VEHICLE OPERATION

(71) Applicant: GM GLOBAL TECHNOLOGY OPERATIONS LLC, Detroit, MI (US)

(72) Inventors: Aaron B. Bloom, Royal Oak, MI (US); Dave Gerard Rich, Sterling Heights, MI (US); Robert A. De Stefano, Macomb Township, MI (US)

(73) Assignee: GM GLOBAL TECHNOLOGY OPERATIONS LLC, Detroit, MI (US)

(21) Appl. No.: 18/153,622

(22) Filed: Jan. 12, 2023

(51) Int. Cl. B60W 10/30; B60R 16/03; B60W 10/26; B60W 60/00; G01R 31/392

(52) U.S. Cl. CPC B60W 10/30; B60R 16/03; B60W 10/26; B60W 60/001; G01R 31/392; B60W 2710/305

(57) ABSTRACT

Vehicles and related systems and methods are provided for managing an electrical system. One method involves determining an estimated power consumption associated with one or more loads coupled to an electrical grid, obtaining a current voltage associated with the electrical grid, identifying an expected duration associated with an operating state associated with the vehicle electrical system, determining an energy threshold for the expected duration associated with the operating state based at least in part on the current voltage and the estimated power consumption, and autonomously operating the vehicle electrical system in a manner that is influenced by the energy threshold associated with the operating state.

### INTRODUCTION

The technical field generally relates to vehicle systems and more particularly relates to prolonging operation of autonomous vehicles.

An autonomous vehicle is a vehicle that is capable of sensing its environment and navigating with little or no user input. An autonomous vehicle senses its environment using sensing devices such as radar, lidar, image sensors, and the like. The autonomous vehicle system further uses information from global positioning systems (GPS) technology, navigation systems, vehicle-to-vehicle communication, vehicle-to-infrastructure technology, and/or drive-by-wire systems to navigate the vehicle.

Vehicle automation has been categorized into numerical levels ranging from Zero, corresponding to no automation with full human control, to Five, corresponding to full automation with no human control. Various automated driver-assistance systems, such as cruise control, adaptive cruise control, and parking assistance systems correspond to lower automation levels, while true “driverless” vehicles correspond to higher automation levels.

An autonomous vehicle typically includes one or more electrically operated actuator devices to control one or more vehicle features such as, but not limited to, a propulsion system, a transmission system, a steering system, and a braking system. Accordingly, it is desirable to provide a fail operational electrical system capable of prolonging operation of the actuator devices to ensure safety and satisfactory user experiences. Other desirable features and characteristics of the present invention will become apparent from the subsequent detailed description and the appended claims, taken in conjunction with the accompanying drawings and the foregoing introduction.

### SUMMARY

Apparatus for a vehicle and related methods for operating a vehicle electrical system are provided. One method of managing a vehicle electrical system involves determining an estimated power consumption associated with one or more loads coupled to an electrical grid, obtaining a current voltage associated with the electrical grid, identifying an expected duration associated with an operating state associated with the vehicle electrical system, determining an energy threshold for the expected duration associated with the operating state based at least in part on the current voltage and the estimated power consumption, and autonomously operating the vehicle electrical system in a manner that is influenced by the energy threshold associated with the operating state. In one aspect, the method involves updating a calibration table associated with the vehicle electrical system to maintain an association between the energy threshold and the operating state, wherein autonomously operating the vehicle electrical system involves autonomously operating at least one of the one or more loads in a manner that is influenced by the energy threshold associated with the operating state using the calibration table.

In another aspect, the method involves determining a current energy capacity associated with an energy source coupled to the electrical grid, wherein autonomously operating the vehicle electrical system involves autonomously operating the vehicle electrical system based on a relationship between the current energy capacity and the energy threshold. In a further aspect, autonomously operating the vehicle electrical system involves adjusting operation of at least one of the one or more loads based on the relationship between the current energy capacity and the energy threshold. In another aspect, the one or more loads includes an actuator device associated with autonomous operation of a vehicle, and adjusting operation involves autonomously operating the actuator device to stop the vehicle when the current energy capacity is less than the energy threshold. In yet another aspect, the method involves identifying a current status associated with an energy source coupled to the electrical grid, wherein determining the energy threshold involves determining the energy threshold based at least in part on the current status associated with the energy source. In a further aspect, identifying the current status involves identifying a current state of health associated with the energy source, wherein determining the energy threshold involves scaling the energy threshold based at least in part on the current state of health. In another aspect, identifying the current status involves identifying a current number of available strings of battery cells associated with the energy source, wherein determining the energy threshold involves scaling the energy threshold based at least in part on the current number of available strings of battery cells. In another aspect, the energy source is a multiple output dynamically adjustable capacity storage system (MODACS).

In one aspect, a non-transitory computer-readable medium is provided that has executable instructions stored thereon that, when executed by a processor, cause the processor to determine an estimated power consumption associated with one or more loads coupled to an electrical grid of a vehicle electrical system, obtain a current voltage associated with the electrical grid, identify an expected duration associated with an operating state associated with the vehicle electrical system, determine an energy threshold for the expected duration associated with the operating state based at least in part on the current voltage and the estimated power consumption, update a calibration table associated with the vehicle electrical system to maintain an association between the energy threshold and the operating state, and autonomously operate the vehicle electrical system in a manner that is influenced by the energy threshold associated with the operating state using the calibration table. In one aspect, the instructions cause the processor to determine a current energy capacity associated with an energy source coupled to the electrical grid, wherein autonomously operating the vehicle electrical system involves autonomously operating the vehicle electrical system based on a relationship between the current energy capacity and the energy threshold. In another aspect, autonomously operating the vehicle electrical system involves adjusting operation of at least one load of the one or more loads based on the relationship between the current energy capacity and the energy threshold. In another aspect, the instructions cause the processor to identify a current status associated with an energy source coupled to the electrical grid, wherein determining the energy threshold involves determining the energy threshold based at least in part on the current status associated with the energy source. In another aspect, the current status includes a current state of health associated with the energy source and determining the energy threshold involves scaling the energy threshold based at least in part on the current state of health. In another aspect, the current status includes a current number of available strings of battery cells associated with the energy source, and determining the energy threshold involves scaling the energy threshold based at least in part on the current number of available strings of battery cells. In a further aspect, the energy source is a multiple output dynamically adjustable capacity storage system (MODACS).

In another aspect, a vehicle is provided that includes an energy source to provide an electrical grid for a vehicle electrical system, one or more loads coupled to the electrical grid; a data storage element to maintain a calibration table including a plurality of energy thresholds associated with a plurality of different operating states for the vehicle electrical system, and a control module coupled to the electrical grid that, by a processor, determines an estimated power consumption associated with the one or more loads, obtains a current voltage associated with the electrical grid, identifies a duration associated with an operating state of the plurality of different operating states, determines an updated energy threshold for the duration associated with the operating state based at least in part on the current voltage and the estimated power consumption, and updates the calibration table to maintain the updated energy threshold in association with the operating state. In one aspect, the autonomous operation of at least one of the one or more loads is influenced by the updated energy threshold associated with the operating state. In another aspect, the vehicle further includes a fail operational power module (FOPM) including the control module, wherein the FOPM transitions operation of the vehicle electrical system from the operating state to a different operating state when a current energy capacity associated with the energy source is less than the updated energy threshold. In another aspect, the energy source is a multiple output dynamically adjustable capacity storage system (MODACS).

### BRIEF DESCRIPTION OF THE DRAWINGS

The exemplary aspects will hereinafter be described in conjunction with the following drawing figures, wherein like numerals denote like elements, and wherein:

FIG. 1 is a block diagram illustrating an electrical system for a vehicle in accordance with various implementations;

FIG. 2 is a block diagram of a multiple output dynamically adjustable capacity storage system (MODACS) suitable for use in the vehicle electrical system of FIG. 1 in accordance with various implementations; and

FIG. 3 depicts a flow diagram of a state transition recalibration process suitable for implementation in connection with a vehicle electrical system according to one or more implementations described herein.

### DETAILED DESCRIPTION

The following detailed description is merely exemplary in nature and is not intended to limit the application and uses. Furthermore, there is no intention to be bound by any expressed or implied theory presented in the preceding introduction, summary, or the following detailed description. As used herein, the term module refers to any hardware, software, firmware, electronic control component, processing logic, and/or processor device, individually or in any combination, including without limitation: application specific integrated circuit (ASIC), an electronic circuit, a processor (shared, dedicated, or group) and memory that executes one or more software or firmware programs, a combinational logic circuit, and/or other suitable components that provide the described functionality.

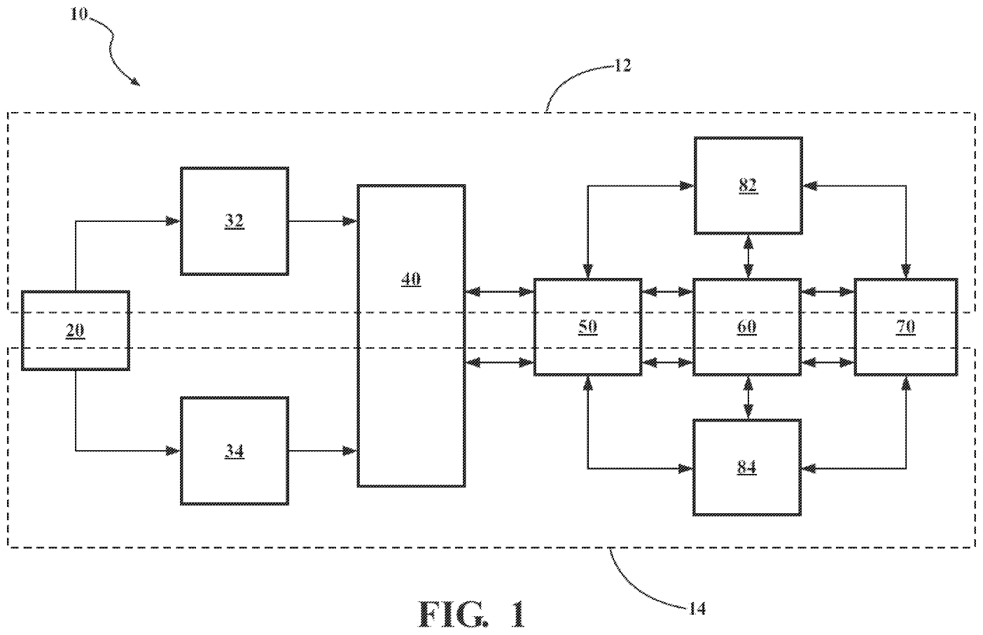

Referring now to FIG. 1, in accordance with one or more implementations, a vehicle electrical system 10 includes a redundant power system including a first grid 12 and a second grid 14, with each grid being independently capable of providing adequate power to operate various electrical loads 50, 60, 70 associated with operating the vehicle.

The illustrated vehicle electrical system 10 includes a battery 20 coupled to a redundant set of accessory power modules (APMs) 32, 34 associated with the respective grids 12, 14 of the redundant power system. In exemplary implementations, the battery 20 is realized as a high voltage (HV) battery that supplies electric power in a suitable voltage range (e.g., 350-800 Volts) to primarily provide power to a vehicle propulsion system.

The APMs 32, 34 generally represent the direct current to direct current (DC-DC) converters or other hardware or circuitry configured to transform electrical energy from the voltage level associated with the HV battery 20 to the respective voltage level associated with the respective grid 12, 14 of the power system. For example, in one exemplary implementation, each of the grids 12, 14 includes a respective power supply rail or bus that is coupled to a respective energy storage element 82, 84 associated with the respective grid 12, 14, where the APMs 32, 34 transform the electrical energy from the voltage level associated with the HV battery 20 to the respective voltage level associated with the energy storage elements 82, 84, for example, to supplementally power the loads 50, 60, 70 or provide charging current to the energy storage elements 82, 84. In one implementation, the energy storage elements 82, 84 are realized as 12 Volt lithium-ion batteries to supply power to vehicle systems (e.g., power windows, a climate control system, and the like), where the APMs 32, 34 support the HV battery 20 providing charging power to one or more of the 12 Volt batteries 82, 84, or vice versa, or the 12 Volt batteries 82, 84 may be used to provide boost propulsion power to the vehicle propulsions system. It should be appreciated that the subject matter described herein is not limited to any particular type or combination of voltage levels, or any particular type, number, or configuration of energy storage elements 82, 84 or the electrical grids 12, 14.

The APMs 32, 34 are coupled to the respective power supply rails of the respective grids 12, 14 via a fail operational power module (FOPM) 40. The FOPM 40 includes a switching arrangement and control module useful to coordinate operation of the first grid 12 and the second grid 14, for example, operating both grids interdependently when the systems are operational and operating one grid independently and isolating the other grid when a problem is detected. In this regard, the FOPM 40 includes at least one processor coupled to the switching arrangement and a computer readable storage device or media configurable to support operation of the FOPM 40 in connection with the vehicle electrical system 100 as described herein. The processor can be any custom made or commercially available processor, a central processing unit (CPU), a graphics processing unit (GPU), an auxiliary processor among several processors associated with a controller associated with the vehicle, a semiconductor-based microprocessor (in the form of a microchip or chip set), a macroprocessor, any combination thereof, or generally any device for executing instructions. The computer readable storage device or media may include volatile and nonvolatile storage in read-only memory (ROM), random-access memory (RAM), and keep-alive memory (KAM), for example. KAM is a persistent or non-volatile memory that may be used to store various operating variables while the processor is powered down. The computer-readable storage device or media may be implemented using any of a number of known memory devices such as PROMs (programmable read-only memory), EPROMs (electrically PROM), EEPROMs (electrically erasable PROM), flash memory, or any other electric, magnetic, optical, or combination memory devices capable of storing data, some of which represent executable instructions.

The instructions may include one or more separate programs that, when executed by the processor, cause the processor to automatically operate the FOPM as described herein based on the logic, calculations, methods, and/or algorithms embodied by the instructions. In various implementations, the control module of the FOPM 40 may be communicatively coupled to one or more other control modules or other systems onboard the vehicle to communicate commands, signals, data or other information between controllers, such as, for example, a vehicle control module (VCM), a battery control module (BCM) associated with the batteries 82, 84, an engine control module (ECM), and/or the like. Depending on the implementation, the FOPM 40 may be communicatively coupled to a controller area network (CAN), a local interconnect network (LIN), a serial network, wireless network and/or another suitable network and/or interface to communicate with other components onboard the vehicle to support the subject matter described herein.

During normal operation of the redundant power system, the HV battery 20, the APM 32, the FOPM 40, and the 12 Volt battery 82 function as a first grid 12 providing power to a nominal load 50, an auxiliary load 60, and a transient load 70, while the HV battery 20, the APM 34, the FOPM 40, and the 12 Volt battery 84 function as the second grid 14 providing power to the nominal load 50, the auxiliary load 60, and the transient load 70. The nominal load 50 generally represents the primary electrical components or subsystems for the vehicle, such as a power steering pump, a transmission system or other electrically operated actuator devices. The auxiliary load 60 generally represents peripheral devices associated with the vehicle, such as, for example, a climate control system including heating and air conditioning of a vehicle passenger compartment, heated glass, and/or the like. The transient load 70 generally represents time limited device usages or tasks, which may include brief but high-demand spikes in energy usage, such as propulsion boost supplied during rapid vehicle acceleration events or navigation up a steep incline.

In practice, the batteries 82, 84 may include any number of constituent battery cells configured to support or otherwise provide a desired voltage level, current (or power) capacity, and/or energy storage capacity. A battery cell may include a single unit including an anode, a cathode, a membrane, and an electrolyte, wherein the battery cell is capable of receiving electrical energy in a charging mode and is capable of providing electrical energy in a discharge mode. In practice, battery cells may be logically grouped or arranged in strings which can be individually operated independent of one another, where each string has an equal number of battery cells per string. In various implementations, multiple strings may be configured in series or parallel to provide a desired voltage level or current capacity.

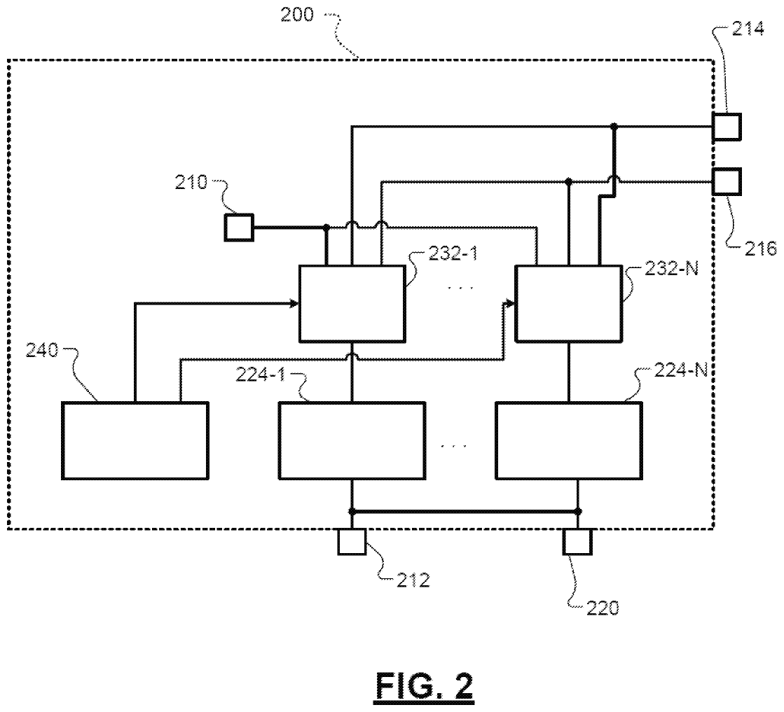

Referring now to FIG. 2, in some implementations, a multiple output dynamically adjustable capacity storage system (MODACS) 200 may be utilized in the vehicle electrical system 100 in lieu of the different energy storage elements 82, 84. In this regard, FIG. 2 depicts a functional block diagram of the MODACS 200 implemented as a single battery having multiple source terminals. For purposes of explanation, three example source terminals 210, 214, 216 are shown, although any number of source terminals may be included. The source terminals, which may be referred to as positive output terminals, provide respective direct current (DC) operating voltages. The MODACS 200 may include only one negative terminal or may include a negative terminal for each source terminal. For example only, the MODACS 200 may have a first positive (e.g., 48 Volt (V)) terminal 210, a first negative terminal 212, a second positive (e.g., a first 12V) terminal 214, a third positive (e.g., a second 12V) terminal 216, and a second negative terminal 220. While the example of the MODACS 200 having a 48V operating voltage and two 12V operating voltages is provided, the MODACS 200 may have one or more other operating voltages, such as only two 12V operating voltages, only two 48V operating voltages, two 48V operating voltages and a 12V operating voltage, or a combination of two or more other suitable operating voltages.

For example, when used in the vehicle electrical system 100 of FIG. 1, a first 12V positive output terminal 214 may be coupled to or otherwise configured to provide the power supply rail for the first grid 12, while a second 12V positive output terminal 216 may be coupled to or otherwise configured to provide the power supply rail for the second grid 14. In this regard, the separate energy storage elements 82, 84 may be absent from the vehicle electrical system 100 in implementations where the MODACS 200 is used in the vehicle electrical system 100 in lieu of the energy storage elements 82, 84, in which case respective output terminals of the MODACS 200 are coupled to or otherwise configured to provide the respective grids 12, 14 of the vehicle electrical system 100.

The MODACS 200 includes cells and/or blocks of cells, such as a first block 224-1 to an N-th block 224-N (“blocks 224”), where N is an integer greater than or equal to 2. Each of the blocks 224 may include one or more cells and may be separately replaceable within the MODACS 200. For example only, each of the blocks 224 may be an individually housed 12V DC battery. The ability to individually replace the blocks 224 may enable the MODACS 200 to include a shorter warranty period and have a lower warranty cost. The blocks 224 are also individually isolatable, for example, in the event of a fault in a block.

In various implementations, the MODACS 200 may have the form factor of a standard automotive grade 12V battery.

Each of the blocks 224 has its own separate capacity (e.g., in amp hours, Ah). The MODACS 200 includes switches, such as first switches 232-1 to 232-N (collectively “switches 232”). The switches 232 enable the blocks 224 to be connected in series, parallel, or combinations of series and parallel to provide desired output voltages and capacities at the output terminals.

A MODACS control module 240 controls the switches 232 to provide desired output voltages and capacities at the source terminals. The MODACS control module 240 controls the switches 232 to vary the capacity provided at the source terminals based on a present operating mode of the vehicle, as discussed further below. Similar to the FOPM 40, in exemplary implementations, the MODACS control module 240 includes at least one processor configurable to control the switches 232 and a computer readable storage device or media configurable to support operation of the MODACS 200 in connection with the vehicle electrical system 100 as described herein. The processor can be any custom made or commercially available processor, a central processing unit (CPU), a graphics processing unit (GPU), an auxiliary processor among several processors associated with a controller associated with the vehicle, a semiconductor-based microprocessor (in the form of a microchip or chip set), a macroprocessor, any combination thereof, or generally any device for executing instructions. The computer readable storage device or media may include volatile and nonvolatile storage in read-only memory (ROM), random-access memory (RAM), and keep-alive memory (KAM), for example. KAM is a persistent or non-volatile memory that may be used to store various operating variables while the processor is powered down. The computer-readable storage device or media may be implemented using any of a number of known memory devices such as PROMs (programmable read-only memory), EPROMs (electrically PROM), EEPROMs (electrically erasable PROM), flash memory, or any other electric, magnetic, optical, or combination memory devices capable of storing data, some of which represent executable instructions. The instructions may include one or more separate programs that, when executed by the processor, cause the processor to automatically operate the switches 232 as described herein based on the logic, calculations, methods, and/or algorithms embodied by the instructions.

In various implementations, the MODACS control module 240 is communicatively coupled to one or more other control modules or other systems onboard the vehicle to communicate commands, signals, data or other information between controllers, such as, for example, a control module associated with the FOPM 40, a VCM, a BCM, an ECM, and/or the like. Depending on the implementation, the MODACS control module 240 may be communicatively coupled to a controller area network (CAN), a local interconnect network (LIN), a serial network, an automotive Ethernet network, a wireless network and/or another suitable network and/or interface to communicate with other components onboard the vehicle to support the subject matter described herein.

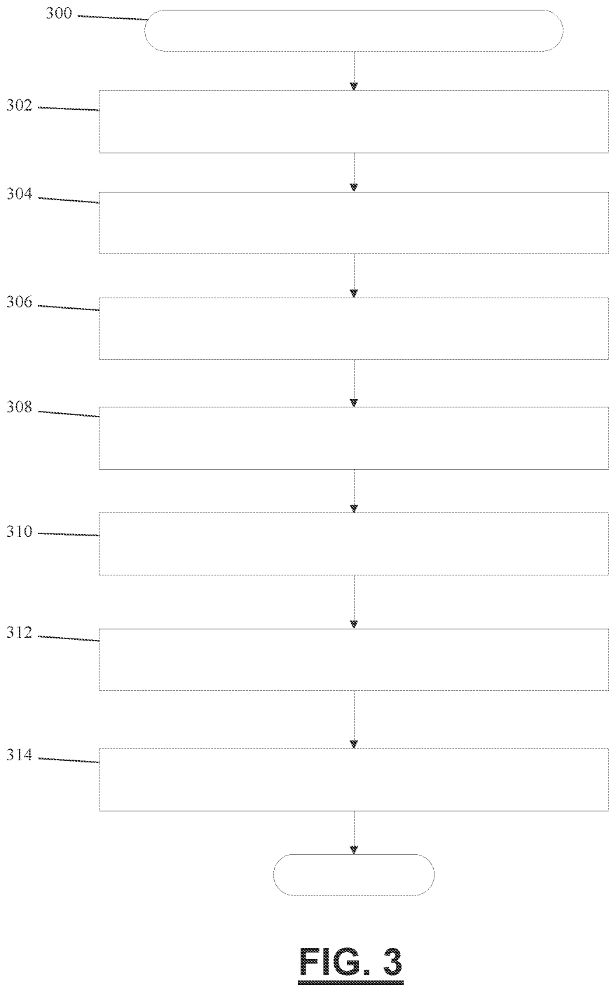

FIG. 3 depicts an exemplary implementation of a self-learning state transition recalibration process 300 suitable for implementation by one or more control modules onboard a vehicle to dynamically update a calibration table maintaining energy thresholds for transitioning between different operating states when terminating operation of the vehicle. In this regard, the values maintained in the calibration table may be referenced or otherwise utilized by one or more of the FOPM 40, the MODACS control module 240, the vehicle loads 50, 60, 70, a BCM, a VCM and/or another control module or system onboard the vehicle to manage energy consumption or utilization in connection with autonomously terminating operation of the vehicle in response to an anomalous condition. For illustrative purposes, the following description may refer to elements mentioned above in connection with FIGS. 1-2. While portions of the state transition recalibration process 300 may be performed by different elements of a vehicle system, for purposes of explanation, the subject matter may be primarily described herein in the context of the state transition recalibration process 300 being primarily performed by the FOPM 40, the MODACS control module 240, or another controller associated with the vehicle.

In exemplary implementations, the state transition recalibration process 300 initializes or otherwise begins in response to identifying or otherwise detecting a recalibration triggering event. In this regard, in some implementations, the recalibration triggering event may be realized as an anomalous condition with respect to one or more components of the vehicle electrical system, such as, for example, an anomalous condition with respect to one of the APMs 32, 34 or an energy source associated with one of the grids 12, 14 (e.g., one of the batteries 82, 84 or the MODACS 200) that triggers the state transition recalibration process 300 to dynamically update the operating state transition thresholds based on the current load on the vehicle electrical system substantially in real-time in response to the anomalous condition. In other implementations, the state transition recalibration process 300 may be periodically triggered in accordance with a predetermined schedule, for example, every three months, every 90 operating cycles, and/or the like. In this manner, the operating state transition thresholds may dynamically vary over time as the expected load on the vehicle electrical system (e.g., due to seasonal weather conditions and/or the like).

The illustrated state transition recalibration process 300 identifies or otherwise determines the current status or condition of the energy source(s) associated with the vehicle electrical system at 302. In this regard, a control module or other controller associated with the vehicle identifies or otherwise determines one or more of the following: the current voltage of the respective electrical grids 12, 14, the current voltage output associated with the available energy sources 82, 84, 200, the current electrical current consumption associated with the respective electrical grids 12, 14, the current electrical current flowing to/from the available energy sources 82, 84, 200, the current state of health (SOH) associated with the available energy sources 82, 84, 200, the current state of charge (SOC) associated with the available energy sources 82, 84, 200, the current temperature associated with the available energy sources 82, 84, 200, and/or potentially other measurement data or information indicative of the current state of the available energy resources (e.g., availability or health of the APMs 32, 34, the HV battery 20, and/or the like). For example, in one or more implementations, the control module of the FOPM 40 may be coupled to or otherwise include one or more sensors configured to sample or otherwise obtain measurements of the voltage associated with the respective grids 12, 14, the output voltage associated with the APMs 32, 34 and/or the current flow to/from the electrical grids 12, 14 (e.g., via the APMs 32, 34). The FOPM 40 may also receive or otherwise obtain, from a control module associated with the grid energy sources (e.g., from the MODACS control module 240, a BCM associated with the batteries 82, 84 and/or the like) indicia of the current state of the available energy sources, including the current SOC, the current SOH, the current temperature, the current voltage, the current status or availability of the strings of battery cells associated with the energy source, and/or the like.

In one or more implementations, the FOPM 40 obtains a plurality of samples for the respective indicator of the electrical system state or condition and then calculates or otherwise determines an average value for the respective state indicator associated with the current iteration of the state transition recalibration process 300. In this regard, the FOPM 40 may periodically sample or otherwise obtain voltage measurements for the electrical grids 12, 14 over a monitoring period of time until a threshold number of samples have been obtained. For example, in implementations where the electrical current output measurements from the APMs 32, 34 are obtained at 1-minute intervals, the FOPM 40 may periodically sample or otherwise obtain measurements of the output current flowing from the APMs 32, 34 to the electrical grids 12, 14 for a monitoring period of 30 minutes to obtain 30 output current samples, which, in turn, may be averaged or otherwise combined to obtain an average current measurement associated with the electrical grids 12, 14.

The state transition recalibration process 300 continues by calculating or otherwise determining an estimated steady state power consumption by the vehicle electrical loads at 304. In this regard, based on the current voltage associated with the electrical grids 12, 14 and the electrical current associated with the electrical grids 12, 14, a corresponding estimated power consumption of the vehicle electrical loads 50, 60, 70. For example, the current (or average) voltage measurement associated with the electrical grids 12, 14 may be multiplied by the average current consumption associated with the electrical grids 12, 14 associated with the preceding monitoring window (e.g., the average current output by the APMs 32, 34 over the preceding 30 minutes) to obtain an estimated power consumption by the electrical loads 50, 60, 70 coupled to the electrical grids 12, 14.

After determining the estimated steady state power consumption by the vehicle electrical loads, the state transition recalibration process 300 identifies or otherwise determines the expected durations for different operating states associated with the vehicle electrical system when sequentially transitioning to terminating vehicle operation at 306. In this regard, different operating states may be defined for the vehicle electrical system in response to anomalous condition, where the different operating states sequentially progress from normal (or non-anomalous) operation of the vehicle system to progressively degraded operating states until a final degradation state where propulsive operation of the vehicle is terminated. For example, in one implementation, a sequence of six degradation states are defined for the vehicle electrical system that range from a normal operating state (DS0) where no anomalies exist to a final degradation state (DS5) where terminating propulsive operation of the vehicle is imminent. An expected duration for each anomalous degradation state (DS1-DS5) may be defined or otherwise configured by a vehicle manufacturer or other user based on various factors which are not germane to this disclosure. For example, an expected duration of 12 seconds may be defined for the final degradation state (DS5) associated with bringing the vehicle to a stop, while an expected duration of 40 seconds may be defined for the penultimate degradation state (DS4) associated with transitioning the vehicle towards stopping, and so on. In this regard, the subject matter described herein is not limited to any particular type, number, configuration or sequence of defined operating states and corresponding durations. For example, some implementations may also define peak power requirements for different degradation states or other operating states, which may vary depending on the particular application, battery size, and potentially other factors.

After identifying the expected duration for each operating state, the state transition recalibration process 300 calculates or otherwise determines the expected energy requirements for the different operating states at 308 based at least in part on the estimated steady state power consumption determined at 304 over the expected duration for the respective operating state. In this regard, the state transition recalibration process 300 multiplies the estimated steady state power consumption by the expected duration associated with a respective operating state to determine the estimated amount of energy capacity required to be available from the energy source(s) 82, 84, 200 to support the operation of the vehicle electrical system 100 and the vehicle loads 50, 60, 70 over the duration of time that the vehicle electrical system 100 is expected to operate in that state.

For example, in one implementation, the estimated energy capacity (in ampere hours (Ah)) required for a respective operating state (E_{DS}) may be governed by or otherwise determined using the equation

$${E}_{DS} = \frac{P}{V} \times {d}_{DS} \times f ,$$

where P represents the estimated steady state power consumption (in Watts), V represents the current grid voltage (in Volts), d_{DS} represents the expected duration of the respective operating state (in hours), and f represents a scaling factor or error guard band having a value greater than one to provide a desired margin of error to account for fluctuations in the power consumption, the duration of the operating state, the grid voltage, and/or the like. In this regard, in some implementations, the scaling factor ( ) may vary or otherwise be dynamically determined based on the current status or condition of the energy source(s) 82, 84, 200, for example, by increasing the value of the scaling factor as the SOH or the temperature of the energy source(s) 82, 84, 200 decreases, as the number of available battery strings decreases, and/or the like. In one example implementation, for an estimated power consumption of 1500 Watts, an average grid voltage of 14 Volts, and an expected duration of the final degradation state (DS5) of 12 seconds, with a scaling factor of 1.1, the estimated energy capacity required for the final degradation state (DS5) may be calculated to be 0.39 Ah. For an expected duration of the penultimate degradation state (DS4) of 40 seconds, the estimated energy capacity required for DS4 degradation state may be calculated to be 1.29 Ah. For an expected duration of 5 minutes for the DS3 degradation state preceding the DS4 degradation state, the estimated energy capacity required for DS3 degradation state may be calculated to be 9.82 Ah, and so on.

After determining the energy requirements for the different operating states, the state transition recalibration process 300 identifies or otherwise determines a desired amount of remaining energy margin after terminating vehicle operation at 310 and then updates a calibration table of energy thresholds for transitioning through the sequence of different operating states based on the different operating state energy requirements and the remaining energy margin at 312. The remaining energy margin represents an amount of energy capacity desired to be available or remaining at the energy source(s) to be supplied to the grids 12, 14 and/or loads 50, 60, 70 after terminating vehicle operation, for example, for passenger convenience. In this regard, the remaining energy margin may be defined by a vehicle manufacturer as a default setting, which, in some implementations, may be configurable by a user or passenger.

To update the calibration table, the state transition recalibration process 300 calculates or otherwise determines an energy capacity threshold for transitioning into the final degradation state DS5 by adding the estimated energy capacity required for the DS5 degradation state to the remaining energy margin to identify a threshold energy capacity for the energy sources 82, 84, 200 at which point the vehicle electrical system 100 is to be transitioned from the DS4 degradation state to the DS5 degradation state. For example, continuing the above example, if the remaining energy margin is set to 5 Ah and the estimated energy capacity required for the DS5 degradation state is calculated as 0.39 Ah, the energy capacity threshold for transitioning into the final degradation state DS5 is determined to be 5.39 Ah. To determine the energy capacity threshold for transitioning into the preceding DS4 degradation state, the estimated energy capacity required for the preceding DS4 degradation state is added to the energy capacity threshold for transitioning into the final degradation state DS5 to arrive at an energy capacity threshold for transitioning into the DS4 degradation state of 6.68 Ah. Similarly, to determine the energy capacity threshold for transitioning into the preceding DS3 degradation state, the estimated energy capacity required for the preceding DS3 degradation state is added to the energy capacity threshold for transitioning into the DS4 degradation state to arrive at an energy capacity threshold for transitioning into the DS3 degradation state of 16.5 Ah, and so on. After determining the energy capacity threshold for transitioning into the different degradation states DS1-DS5, the state transition recalibration process 300 dynamically updates a calibration table maintained in a data storage or memory by rewriting existing values for the energy capacity thresholds for the different degradation states DS1-DS5 with the most recently determined values. In this regard, the calibration table may be initially configured with entries maintaining associations between default values for the energy capacity thresholds and the respective degradation states DS1-DS5, which may have been previously defined or programmed by a vehicle manufacturer or other user based on a nominal power consumption and nominal grid voltage for the vehicle. Thus, as the actual operation of the vehicle electrical system 100 varies from the nominal expectations (e.g., based on different user behaviors, different geographic regions, different meteorological conditions, and/or the like), the energy capacity thresholds are dynamically updated to reflect the actual usage or operation.

After updating the calibration table, the state transition recalibration process 300 continues by autonomously operating the vehicle electrical system in accordance with the updated state transition thresholds maintained in the calibration table at 314. In this regard, the calibration table may be stored or maintained in a data storage element accessible to one or more of the FOPM 40, the electrical loads 50, 60, 70, the controllers associated with the energy source(s) 82, 84, 200 (e.g., a BCM or MODACS control module 240), the APMs 32, 34 and/or the like, where the respective component of the vehicle electrical system 100 may be configurable to autonomously adjust its operation or communicate with another component of the vehicle electrical system 100 to adjust power consumption. For example, the FOPM 40 may continually monitor the energy capacity of the energy source(s) 82, 84, 200 to identify or otherwise determine when to transition from one degradation state to the next degradation state of the sequence based on the relationship between the current energy capacity and the recalibrated value for the energy transition threshold into the next degradation state. Continuing the above example, when the vehicle electrical system 100 is currently operating in accordance with the DS2 degradation state, the FOPM 40 may monitor the energy capacity of the energy source(s) 82, 84, 200 to detect or otherwise identify when the remaining available energy capacity of the energy source(s) 82, 84, 200 falls below 16.5 Ah. In response to the remaining available energy capacity falling below the state transition threshold of 16.5 Ah, the FOPM 40 may determine the updated operating state of the vehicle electrical system 100 to be the DS3 degradation state and provide corresponding commands, instructions, signals or other indicia of the updated degradation state to one or more of the electrical loads 50, 60, 70, the controllers associated with the energy source(s) 82, 84, 200 (e.g., a BCM or MODACS control module 240), the APMs 32, 34 and/or the like.

For example, in some implementations, in response to receiving indication of the DS3 degradation state, one or more of the electrical loads 50, 60, 70, the controllers associated with the energy source(s) 82, 84, 200 (e.g., a BCM or MODACS control module 240) and/or the APMs 32, 34 may autonomously adjust its operation in accordance with the DS3 degradation state (e.g., based on logic rules or other settings associated with the DS3 degradation state maintained at the respective component). For example, in some implementations, the FOPM 40 may command, signal, or otherwise instruct one of the electrical loads 50, 60, 70 to terminate operation or otherwise cease power consumption based on the current degradation state in order to reduce power consumption, and thereby prolong operation of the vehicle (e.g., by delaying the time when the available energy capacity is likely to fall below the next state transition threshold). That said, in other implementations, a respective one of the electrical loads 50, 60, 70, the controllers associated with the energy source(s) 82, 84, 200 (e.g., a BCM or MODACS control module 240) and/or the APMs 32, 34 may access or otherwise reference the calibration table to monitor the relationship between the current energy capacity and the recalibrated value for the energy transition threshold into the next degradation state. For example, while in the DS3 degradation state, if the current energy capacity is decreasing faster than expected or otherwise approaching the DS4 energy capacity transition threshold, an electrical load 50, 60, 70 may autonomously attempt to reduce its power (or current) consumption to delay the degradation state transition, or a controller associated with an energy source 82, 84, 200 may autonomously adjust operation to attempt to prolong its energy capacity.

It should be appreciated that the state transition recalibration process 300 effectively provides a self-learning algorithm to rewrite the degradation state calibration derating table, which, in turn, may allow for vehicles to operate in a respective degradation state for a longer period of time or otherwise delaying degradation state transitions for vehicles having lower electrical loads (or lower power consumption), thereby improving passenger experience and extending battery life relative to using default values corresponding to a worst case steady state assumption. For example, in some implementations, the state transition recalibration process 300 is automatically triggered in response to an anomalous condition that results in a DS2 degradation state or DS3 degradation state to recalibrate the derating table to dynamically narrow or broaden the energy and power windows for the energy source(s) to increase battery life and/or ensure maneuverability of the vehicle (e.g., for the DS5 degradation state where one or more of the electrical loads 50, 60, 70 include actuator devices associated with autonomously stopping propulsion of the vehicle). In this regard, the updated calibration table may be referenced or otherwise utilized by the MODACS control module 240, a BCM, a VCM, the control module of the FOPM 40, or a control module associated with any one of the electrical loads 50, 60, 70, where the software or other logic or rules configured or implemented at the respective component automatically determines how to respond to the updated (or recalibrated) state transition threshold values. In other words, the updated calibration table drives the software at a respective vehicle component, where the software at the respective vehicle component autonomously determines how to autonomously adjust its operation in accordance with the updated state transition threshold values. Accordingly, it should be appreciated that there are numerous different potential configurations or combinations for how the state transition thresholds maybe utilized to influence operations of vehicle components in the context of a vehicle electrical system 100, and the subject matter described herein is not intended to be limited to any particular configuration or action(s) responsive to the updated (or recalibrated) state transition thresholds.

While at least one exemplary aspect has been presented in the foregoing detailed description, it should be appreciated that a vast number of variations exist. It should also be appreciated that the exemplary aspect or exemplary aspects are only examples, and are not intended to limit the scope, applicability, or configuration of the disclosure in any way. Rather, the foregoing detailed description will provide those skilled in the art with a convenient road map for implementing the exemplary aspect or exemplary aspects. It should be understood that various changes can be made in the function and arrangement of elements without departing from the scope of the disclosure as set forth in the appended claims and the legal equivalents thereof.

What is claimed is:

1. A method of managing a vehicle electrical system, the method comprising:
determining an estimated power consumption associated with one or more loads coupled to an electrical grid;
obtaining a current voltage associated with the electrical grid;
identifying an expected duration associated with an operating state associated with the vehicle electrical system;
determining an energy threshold for the expected duration associated with the operating state based at least in part on the current voltage and the estimated power consumption; and
autonomously operating the vehicle electrical system in a manner that is influenced by the energy threshold associated with the operating state.

2. The method of claim 1, further comprising updating a calibration table associated with the vehicle electrical system to maintain an association between the energy threshold and the operating state, wherein autonomously operating the vehicle electrical system comprises autonomously operating at least one of the one or more loads in a manner that is influenced by the energy threshold associated with the operating state using the calibration table.

3. The method of claim 1, further comprising determining a current energy capacity associated with an energy source coupled to the electrical grid, wherein autonomously operating the vehicle electrical system comprises autonomously operating the vehicle electrical system based on a relationship between the current energy capacity and the energy threshold.

4. The method of claim 3, wherein autonomously operating the vehicle electrical system comprises adjusting operation of at least one of the one or more loads based on the relationship between the current energy capacity and the energy threshold.

5. The method of claim 3, wherein:
the one or more loads includes an actuator device associated with autonomous operation of a vehicle; and
adjusting operation comprises autonomously operating the actuator device to stop the vehicle when the current energy capacity is less than the energy threshold.

6. The method of claim 1, further comprising identifying a current status associated with an energy source coupled to the electrical grid, wherein determining the energy threshold comprises determining the energy threshold based at least in part on the current status associated with the energy source.

7. The method of claim 6, wherein identifying the current status comprises identifying a current state of health associated with the energy source, wherein determining the energy threshold comprises scaling the energy threshold based at least in part on the current state of health.

8. The method of claim 6, wherein identifying the current status comprises identifying a current number of available strings of battery cells associated with the energy source, wherein determining the energy threshold comprises scaling the energy threshold based at least in part on the current number of available strings of battery cells.

9. The method of claim 6, wherein the energy source comprises a multiple output dynamically adjustable capacity storage system (MODACS).

10. A non-transitory computer-readable medium comprising executable instructions that, when executed by a processor, cause the processor to:
determine an estimated power consumption associated with one or more loads coupled to an electrical grid of a vehicle electrical system;
obtain a current voltage associated with the electrical grid;
identify an expected duration associated with an operating state associated with the vehicle electrical system;
determine an energy threshold for the expected duration associated with the operating state based at least in part on the current voltage and the estimated power consumption;
update a calibration table associated with the vehicle electrical system to maintain an association between the energy threshold and the operating state; and
autonomously operate the vehicle electrical system in a manner that is influenced by the energy threshold associated with the operating state using the calibration table.

11. The non-transitory computer-readable medium of claim 10, wherein the instructions cause the processor to determine a current energy capacity associated with an energy source coupled to the electrical grid, wherein autonomously operating the vehicle electrical system comprises autonomously operating the vehicle electrical system based on a relationship between the current energy capacity and the energy threshold.

12. The non-transitory computer-readable medium of claim 11, wherein autonomously operating the vehicle electrical system comprises adjusting operation of at least one load of the one or more loads based on the relationship between the current energy capacity and the energy threshold.

13. The non-transitory computer-readable medium of claim 10, wherein the instructions cause the processor to identify a current status associated with an energy source coupled to the electrical grid, wherein determining the energy threshold comprises determining the energy threshold based at least in part on the current status associated with the energy source.

14. The non-transitory computer-readable medium of claim 13, wherein:
the current status comprises a current state of health associated with the energy source; and
determining the energy threshold comprises scaling the energy threshold based at least in part on the current state of health.

15. The non-transitory computer-readable medium of claim 13, wherein:
the current status comprises a current number of available strings of battery cells associated with the energy source; and
determining the energy threshold comprises scaling the energy threshold based at least in part on the current number of available strings of battery cells.

16. The non-transitory computer-readable medium of claim 15, wherein the energy source comprises a multiple output dynamically adjustable capacity storage system (MODACS).

17. A vehicle comprising:
an energy source to provide an electrical grid for a vehicle electrical system;
one or more loads coupled to the electrical grid;
a data storage element to maintain a calibration table including a plurality of energy thresholds associated with a plurality of different operating states for the vehicle electrical system; and
a control module coupled to the electrical grid that, by a processor, determines an estimated power consumption associated with the one or more loads, obtains a current voltage associated with the electrical grid, identifies a duration associated with an operating state of the plurality of different operating states, determines an updated energy threshold for the duration associated with the operating state based at least in part on the current voltage and the estimated power consumption, and updates the calibration table to maintain the updated energy threshold in association with the operating state.

18. The vehicle of claim 17, wherein autonomous operation of at least one of the one or more loads is influenced by the updated energy threshold associated with the operating state.

19. The vehicle of claim 17, further comprising a fail operational power module (FOPM) including the control module, wherein the FOPM transitions operation of the vehicle electrical system from the operating state to a different operating state when a current energy capacity associated with the energy source is less than the updated energy threshold.

20. The vehicle of claim 17, wherein the energy source comprises a multiple output dynamically adjustable capacity storage system (MODACS).
